(19) United States
(12) Patent Application Publication
(10) Pub. No.: US 2004/0135243 A1
(43) Pub. Date: Jul. 15, 2004

(54) Semiconductor device, its manufacturing method and electronic device

(75) Inventor: Akiyoshi Aoyagi, Sakata-shi (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/719,888

(22) Filed: Nov. 21, 2003

(30) Foreign Application Priority Data
Nov. 25, 2002 (JP) 2002-340879

(51) Int. Cl. H01L 23/02

(52) U.S. Cl. 257/686

(57) ABSTRACT

A semiconductor device includes a base substrate including a base wiring pattern. A first circuit substrate is disposed over the base substrate and includes a first wiring pattern. A first semiconductor element is mounted on the first circuit substrate and includes a first electrode that is electrically connected to the first wiring pattern. A second circuit substrate is disposed over the first circuit substrate and includes a second wiring pattern and a second semiconductor element is mounted on the second circuit substrate and includes a second electrode that is electrically connected to the second wiring pattern. A first protruded electrode is electrically connected to the first wiring pattern and provided protruding from the first circuit substrate and bonded to the base wiring pattern and a second protruded electrode is electrically connected to the second wiring pattern and provided protruding from the second circuit substrate and bonded to the base wiring pattern.

### BACKGROUND OF THE INVENTION

1. Field of the Invention

The present invention relates to semiconductor devices, methods for manufacturing the same, and electronic devices.

2. Description of Related Art

In order to mount semiconductor elements with a high density, there has been proposed a technique to stack a plurality of semiconductor elements in layers in their thickness direction. More specifically, a plurality of circuit substrates having semiconductor elements mounted thereon are mutually connected, and a circuit substrate in the lowermost layer and a base substrate are electrically connected, such that they are mounted and stacked in layers.

Solder balls, for example, may be used to mutually electrically connect the circuit substrates. Terminals of only the circuit substrate on the lowermost layer may be connected to the base substrate.

However, in the conventional technology described above, when semiconductor elements of different types are to be used, each of the circuit substrates needs wirings that can be accommodated by each of the semiconductor elements located above the circuit substrate, which may cause each of the circuit substrates to have a large area, or may diminish the degree of freedom in routing the wirings. In this manner, when the number of wirings increases, the area of the circuit substrate and the base substrate may become large, or the degree of freedom in designing wirings within the circuit substrate and the base substrate is lowered due to the area limitations of the circuit substrate and the base substrate.

Also, even when semiconductor elements of the same type are used, when a plurality of semiconductor memory elements are to be stacked in layers, wirings for selecting the semiconductor memory elements, which are to be provided independent of the other wirings, are required, and therefore another circuit substrate for such wirings may be further required.

Also, because the circuit substrates to be stacked in layers need to be mutually connected with solder balls or the like, forming a thinner body of stacked layers may be prevented.

The present invention has been made in view of the circumstances described above, and its an aspect of the present invention to provide semiconductor devices, methods for manufacturing the same and electronic devices, which can improve the degree of freedom in wire designs within each circuit substrate and base substrate, reduce the number of components, and achieve a thinner body of stacked layers.

### SUMMARY OF THE INVENTION

A semiconductor device in accordance with the present invention includes a base substrate including a base wiring pattern. A first circuit substrate is disposed over the base substrate and includes a first wiring pattern. A first semiconductor element is mounted on the first circuit substrate and includes a first electrode that is electrically connected to the first wiring pattern. A second circuit substrate is disposed over the first circuit substrate and includes a second wiring pattern and a second semiconductor element is mounted on the second circuit substrate and includes a second electrode that is electrically connected to the second wiring pattern. A first protruded electrode is electrically connected to the first wiring pattern and provided protruding from the first circuit substrate and bonded to the base wiring pattern and a second protruded electrode is electrically connected to the second wiring pattern and provided protruding from the second circuit substrate and bonded to the base wiring pattern.

Also, a method for manufacturing a semiconductor device in accordance with the present invention includes disposing a first circuit substrate, which is a circuit substrate having a first wiring pattern, having a first semiconductor element mounted thereon including a first electrode that is electrically connected to the first wiring pattern over a base wiring substrate including a base wiring pattern The method also includes bonding a first protruded electrode provided between the first circuit substrate and the base substrate to the base wiring pattern to electrically connect the first wiring pattern and the base wiring pattern. The method further includes disposing a second circuit substrate, which is a circuit substrate including a second wiring pattern, having a second semiconductor element mounted thereon including a second electrode that is electrically connected to the second wiring pattern over the first circuit substrate. The method also includes bonding a second protruded electrode provided between the second circuit substrate and the base substrate to the base wiring pattern to electrically connect the second wiring pattern and the base wiring pattern.

According to the semiconductor device and its manufacturing method in accordance with the present invention, the degree of freedom in designing wirings within each circuit substrate and base substrate can be improved, the number of components can be reduced, and a thinner body of stacked layers can be achieved.

An electronic device in accordance with the present invention is characterized in comprising the semiconductor device described above. As a result, the electronic device can be made smaller in size and thinner.

### BRIEF DESCRIPTION OF THE DRAWINGS

FIG. 1 shows a semiconductor device in accordance with an embodiment of the present invention.

FIG. 2 shows a semiconductor device in accordance with an embodiment of the present invention.

FIG. 3 shows a semiconductor device in accordance with an embodiment of the present invention.

FIG. 4 shows a semiconductor device in accordance with an embodiment of the present invention.

FIG. 5 shows a semiconductor device in accordance with an embodiment of the present invention.

FIG. 6 shows a semiconductor device in accordance with an embodiment of the present invention.

FIG. 7 shows a semiconductor device in accordance with an embodiment of the present invention.

FIGS. 8(a)-(c) show a method for manufacturing a semiconductor device in accordance with an embodiment of the present invention.

### DETAILED DESCRIPTION OF THE PREFERRED EMBODIMENTS

Embodiments of the present invention are described below.

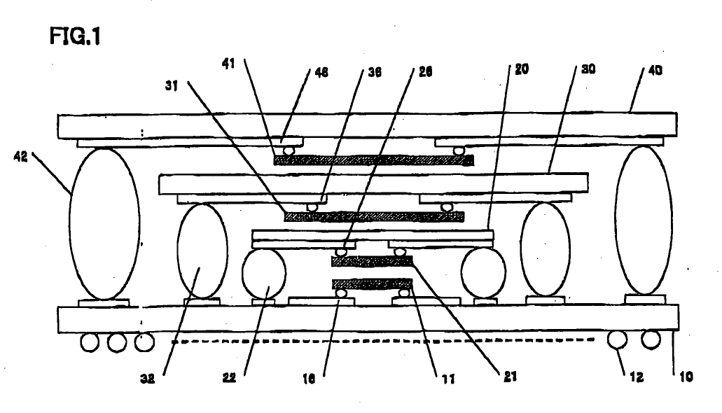

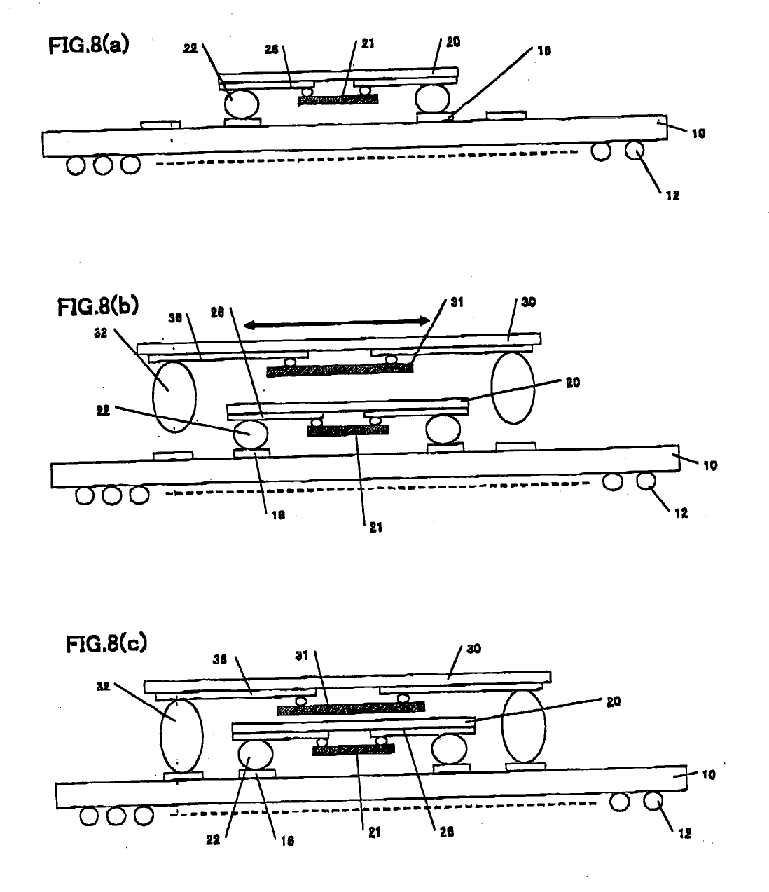

FIGS. 1 through 7 show semiconductor devices in accordance with embodiments of the present invention. FIGS. 8(a)-8(c) show a method for manufacturing the same.

A semiconductor device in accordance with an embodiment of the present invention includes a base substrate 10 and a plurality of circuit substrates 20 and 30. As indicated in FIG. 1, the circuit substrate 30 is located above the circuit substrate 20. Furthermore, one or a plurality of other circuit substrates may be provided over the circuit substrate 30 or between the circuit substrate 20 and the circuit substrate 30.

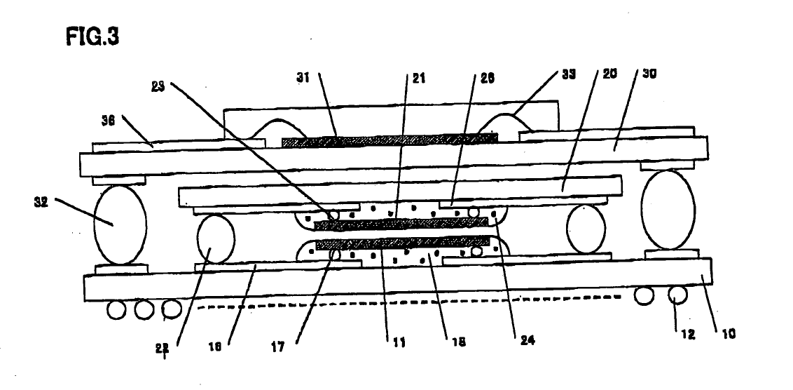

The base substrate 10 is equipped with a dielectric substrate material with a base wiring pattern 16 provided on a surface of the dielectric substrate material. The base wiring pattern may also be provided within the dielectric substrate material to have a multiple-layered wiring structure. Alternatively, the base wiring pattern may be provided on one of the opposing two main surfaces of the dielectric substrate material to have a single-surface mounted wiring structure. Also, the base wiring pattern may be provided on both of the opposing main surfaces of the dielectric substrate material to have a two-surface mounted wiring structure. A semiconductor element 11 may be mounted on the base substrate 10. The semiconductor element 11 may include electrodes 17 indicated in FIG. 3 on its surface. The base substrate 10 is formed with external terminals 12 that are electrically connected to a base wiring pattern 16. The external terminals 12 may be formed from, for example, protruded electrodes that protrude from the surface of the base substrate, leads or conducting pins. The base wiring pattern may include lands that are bonded to protruded electrodes 22, lands that are bonded to protruded electrodes 32, and lands that are bonded to protruded electrodes 42. These lands may be electrically connected to the respective external terminals 12 by wirings.

The circuit substrate 20 is positioned above the base substrate 10. The circuit substrate 20 includes a wiring pattern 26 that is provided in the dielectric substrate material and on a surface of the dielectric substrate material. The wiring pattern may also be provided within the dielectric substrate material to have a multiple-layered wiring structure. Alternatively, the wiring pattern may be provided on one of the opposing main surfaces of the dielectric substrate material to have a single-surface mounted wiring structure. Alternatively, it may be provided on both of the opposing main surfaces of the dielectric substrate material to have a two-surface mounted wiring structure.

A semiconductor element 21 is mounted on the circuit substrate 20. The semiconductor element 21 may include electrodes 23 indicated in FIG. 3 on its surface. The electrodes 23 of the semiconductor element 21 are electrically connected to the wiring pattern 26 of the circuit substrate 20. The electrodes 23 are electrically connected to an integrated circuit provided within the semiconductor element 21, and is provided on a surface of the semiconductor element 21. The electrodes 23 may be formed only from electrode pads, or may include electrode pads and protruded electrodes that are provided on the electrode pads. Also, as indicated in FIG. 3, the semiconductor element 21 may be electrically connected to the wiring pattern 26 of the circuit substrate 20 by a face-down bonding method, or they may be electrically connected by a wire-bonding method.

The base wiring pattern 16 of the base substrate 10 and the wiring pattern 26 of the circuit substrate 20 are electrically connected by using the protruded electrodes 22. The protruded electrodes 22 are electrically connected to the wiring patterns 26 and are provided in a manner protruding from the surface of the circuit substrate 20. The protruded electrodes 22 are provided between the circuit substrate 20 and the base substrate 10. The protruded electrodes 22 are bonded to the wiring pattern 16 of the base substrate 10. For bonding them, any known bonding technique can be used, such as bonding with an adhesive using only an anisotropic conductive adhesive or a dielectric adhesive, or alloy bonding, metal bonding by using inter-metal diffusion bonding or the like.

The circuit substrate 30 is positioned above the circuit substrate 20. The circuit substrate 30 includes a wiring pattern 36. A semiconductor element 31 is mounted on the circuit substrate 30. The semiconductor element 31 includes electrodes provided on its surface. The electrodes of the semiconductor element 31 are electrically connected to the wiring pattern 36 of the circuit substrate 30. The electrodes are electrically connected to an integrated circuit provided within the semiconductor element 31, and are provided on a surface of the semiconductor element 31. The electrodes may be formed from electrode pads, or may include electrode pads and protruded electrodes provided on the electrode pads. As shown in FIG. 3, the electrodes of the semiconductor element 31 may be electrically connected to the wiring pattern 36 of the circuit substrate 30 by a face-down bonding method, or they may be electrically connected by a wire-bonding method using wires 33. The base wiring pattern 16 of the base substrate 10 and the wiring pattern 36 of the circuit substrate 30 are electrically connected by using the protruded electrodes 32. The protruded electrodes 32 are electrically connected to the wiring patterns 16 and 36 and are provided in a manner protruding from the surface of the circuit substrate 30. The protruded electrodes 32 are provided between the circuit substrate 30 and the base substrate 10. The protruded electrodes 32 are bonded to the wiring pattern 16 of the base substrate 10. For bonding them, any known bonding technique can be used, such as bonding with an adhesive using only an anisotropic conductive adhesive or a dielectric adhesive, or alloy bonding, metal bonding by using inter-metal diffusion bonding or the like.

The thickness of the protruded electrodes 32 is greater than the thickness of the protruded electrodes 22. As a result, the circuit substrate 30 can be positioned over the circuit substrate 20. The protruded electrodes 22 and 32 are formed from a conductive member. The conductive member may include a structure in which a plurality of conductive films are stacked in layers. The conductive member may be formed from metal, metal compound, alloy, conductive paste, solder material such as solder, or a mixture of the above. The protruded electrodes 22 and 32 may be provided in the shape of balls, or may be formed with their side surfaces being flat.

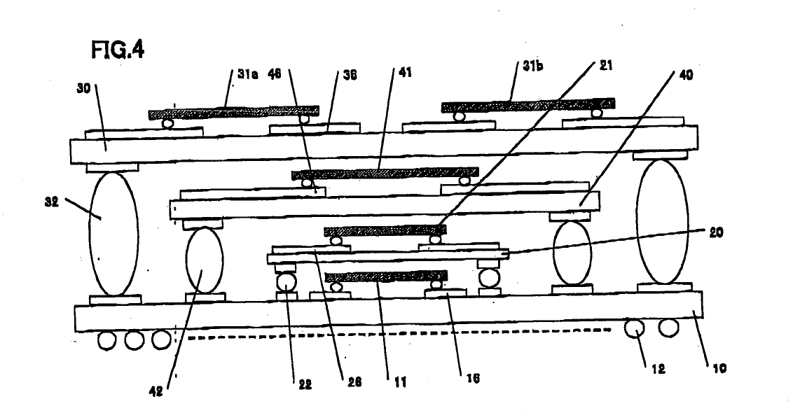

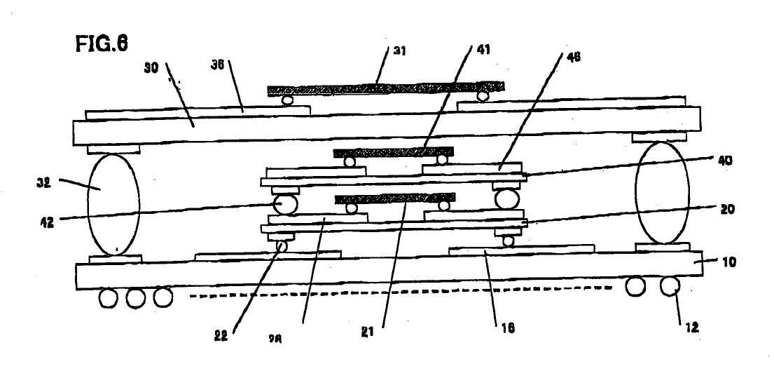

One or a plurality of circuit substrates (for example, a circuit substrate 40) may further be positioned over the circuit substrate 30. Also, as shown in FIG. 4 or FIG. 6, one or a plurality of circuit substrates (for example, a circuit substrate 40) may further be positioned between the circuit substrate 20 and the circuit substrate 30. If, for example, the circuit substrate 40 is provided, a semiconductor element 41 having electrodes is mounted on the circuit substrate 40 including a wiring pattern 46, and the electrodes of the semiconductor element 41 are electrically connected to the wiring pattern 46.

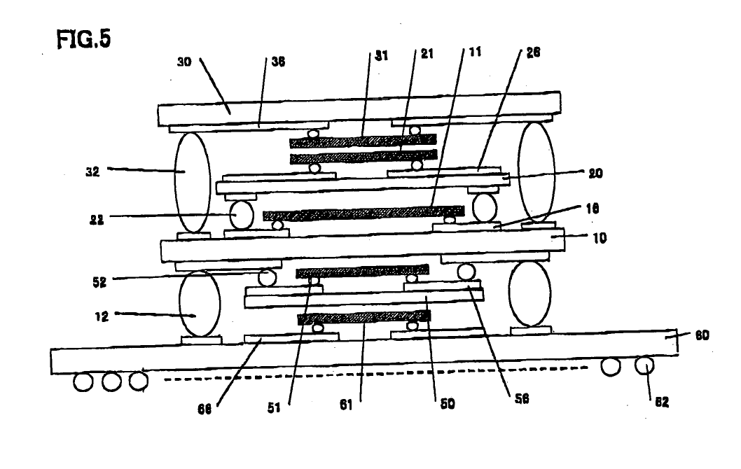

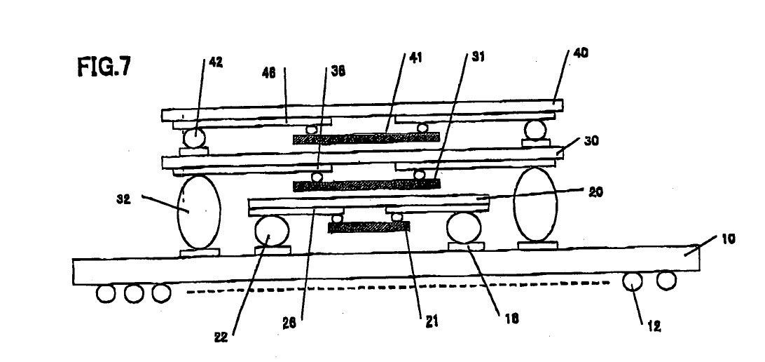

The protruded electrodes 42 are electrically connected to the wiring pattern 46. The base wiring pattern 16 of the base substrate 10 and the wiring pattern 46 of the circuit substrate 40 are electrically connected, using protruded electrodes 42 that protrude from the surface of the circuit substrate 40. The protruded electrodes 42, as indicated in FIG. 1 or FIG. 4, may be bonded to the wiring pattern 16 of the base substrate 10 such that they are electrically connected. For bonding them, any known bonding technique can be used, such as bonding with an adhesive using only an anisotropic conductive adhesive or a dielectric adhesive, or alloy bonding, metal bonding by using inter-metal diffusion bonding or the like. Alternatively, as indicated in FIG. 6 or FIG. 7, the protruded electrodes 42 may be bonded to the wiring pattern 26 or 36 of the circuit substrate 20 or 30, respectively, for example, and may be electrically connected to the wiring pattern 16 of the base substrate 10 through another wiring pattern. As indicated in FIG. 5, circuit substrates may be disposed on both sides of the base substrate 10. Referring to FIG. 5, circuit substrates 20 and 30 are disposed over one of the surfaces of the base substrate 10, and circuit substrates 50 and 60 are disposed over the other surface of the base substrate 10.

Each of the base substrate 10 and the circuit substrates 20, 30 and 40 may be formed from a rigid substrate or a flexible substrate. In the case of a rigid substrate, its dielectric substrate material may be composed of glass epoxy material. In the case of a flexible substrate, its dielectric substrate material may be composed of polyimide material or polyethylene-terephthalate material. Also, semiconductor elements in different types, or semiconductor elements of the same type, may be mounted on the base substrate 10 and the circuit substrates 20, 30 and 40. The semiconductor elements of different types may be semiconductor elements in which electrodes on the surfaces of the semiconductor elements are disposed differently one from the other. The semiconductor elements of the same type may be semiconductor elements in which electrodes on the surfaces of the semiconductor elements are disposed in the same manner.

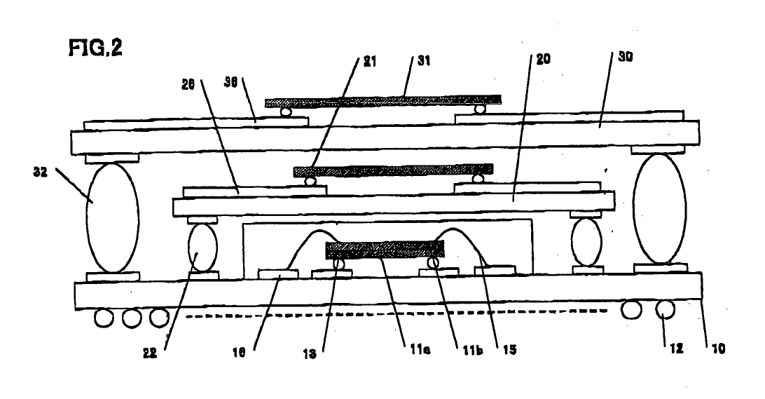

The semiconductor elements 11, 21, 31 and 41 may be mounted on lower surfaces or upper surfaces of the base substrate 10, and the circuit substrates 20, 30 and 40, respectively. When a plurality of semiconductor elements are mounted on at least one of the base substrate 10, and the circuit substrates 20, 30 and 40, the semiconductor elements may be mounted on both surfaces thereof. In accordance with the present embodiment, the description is made as to the case where one semiconductor element is mounted on each of the base substrate 10, and the circuit substrates 20, 30 and 40. However, without being limited to this example, a plurality of semiconductor elements stacked in layers may be mounted on at least one of the base substrate 10, and the circuit substrates 20, 30 and 40, like semiconductor elements 11a and 11b shown in FIG. 2. In this case, the reparability is improved when defects are found by testing, and the manufacturing cost can be reduced. Like the semiconductor element 11a indicated in FIG. 2, a semiconductor element on the lower layer may be connected to at least one of the base substrate 10 and the circuit substrates 20, 30 and 40 by a facedown bonding method. In this case, like the semiconductor element 11b, a semiconductor element on the upper layer is affixed to a rear surface opposite to the surface where electrodes of the semiconductor element on the lower layer are located, and may be connected to at least one of the wiring patterns 16 by wires 15 by a wire bonding method. Also, like semiconductor elements 31a and 31b shown in FIG. 4, a plurality of semiconductor elements may be mounted on at least one of the base substrate 10 and the circuit substrates 20, 30 and 40. In this case, high density mounting of semiconductor elements can be realized, and the thickness of the semiconductor device can be reduced. The semiconductor elements 11, 21, 31 and 41 can be sealed with resin 18, 24 as indicated in FIG. 3.

Next, a method for manufacturing a semiconductor device having the structure described above is described.

First, a circuit substrate 20 having a semiconductor element 21 mounted thereon and a circuit substrate 30 having a semiconductor element 31 mounted thereon are prepared. The semiconductor element 21 includes electrodes to be electrically connected to a wiring pattern 26 of the circuit substrate 20. The semiconductor element 31 includes electrodes to be electrically connected to a wiring pattern 36 of the circuit substrate 30. Further, if another circuit substrate, for example, a circuit substrate 40, is mounted over a base substrate 10, there is provided the circuit substrate 40 having a semiconductor element 41 mounted thereon that includes electrodes to be electrically connected to a wiring pattern 46 of the circuit substrate 40.

The circuit substrate 20 having the semiconductor element 21 mounted thereon is prepared by electrically connecting electrodes provided on the surface of the semiconductor element 21 to the wiring pattern 26 of the circuit substrate 20. In this instance, the semiconductor element 21 and the circuit substrate 20 may be placed with a surface of the semiconductor element 21 having electrodes provided thereon being opposed to a surface of the circuit substrate 20, and the electrodes and the wiring pattern 26 are electrically connected by a facedown bonding method or with a rear surface of the semiconductor element 21 opposite its surface where the electrodes are provided being opposed to a surface of the circuit substrate 20, and the electrodes and the wiring pattern 26 are electrically connected by a wire bonding method. The electrodes and the wiring pattern 26 may be bonded with an adhesive using an anisotropic conductive adhesive, a conductive adhesive, a dielectric adhesive or the like, or bonded with metal bonding through forming eutectic alloy or using inter-metal diffusion or the like, or bonded by wire bonding. The semiconductor element 21 electrically connected to the wiring pattern 26 may be sealed with resin 18, 24.

Like the circuit substrate 20 having the semiconductor element 21 mounted thereon, the circuit substrate 30 including the semiconductor element 31 mounted thereon that have electrodes electrically connected to the wiring pattern 36 of the circuit substrate 30 is prepared by electrically connecting the electrodes of the semiconductor element 31 and the wiring pattern 36 of the circuit substrate 30. The semiconductor element 31 and the circuit substrate 30 may be placed with a surface of the semiconductor element 31 having electrodes provided thereon being opposed to a surface of the circuit substrate 30, and the electrodes and the wiring pattern 36 are electrically connected by a facedown bonding method or with a rear surface of the semiconductor element 31 opposite its surface where the electrodes are provided being opposed to a surface of the circuit substrate 30, and the electrodes and the wiring pattern 36 may be electrically connected with wires 33 by a wire bonding method. The electrodes and the wiring pattern 36 may be bonded with an adhesive using an anisotropic conductive adhesive, a conductive adhesive, a dielectric adhesive or the like, or bonded with metal bonding through forming eutectic alloy or using inter-metal diffusion or the like, or bonded by wire bonding. The semiconductor element 31 electrically connected to the wiring pattern 36 may be sealed with resin.

The protruded electrodes 22, which protrude from the surface of the circuit substrate 20, are provided on a surface of the circuit substrate 20 where the semiconductor element 21 is mounted or on its rear surface. The protruded electrodes 22 may be provided before the semiconductor element 21 is mounted on the circuit substrate 20, or after the semiconductor element 21 is mounted on the circuit substrate 20. Also, the protruded electrodes 32, which protrude from the surface of the circuit substrate 30, are provided on a surface of the circuit substrate 30 where the semiconductor element 31 is mounted or on its rear surface. The protruded electrodes 32 may be provided before the semiconductor element 31 is mounted on the circuit substrate 30, or after the semiconductor element 31 is mounted on the circuit substrate 30.

Protruded electrodes 22 are provided at and electrically connected to a wiring pattern 26 of the circuit substrate 20. The protruded electrodes 32 are provided at and electrically connected to a wiring pattern 36 of the circuit substrate 30. At least the protruded electrodes 22 or the protruded electrodes 32 are formed for example, by solder balls being placed on and electrically connected to the wiring patterns 26 and 36, respectively, and heated to form the protruded electrodes. Also, without being limited to the method that uses solder balls, a plating method may be used to deposit a plating metal to form at least the protruded electrodes 22 or 32.

Further, if another circuit substrate, for example, a circuit substrate 40, is provided, electrodes of a semiconductor element 41 are electrically connected to a wiring pattern 46 of the circuit substrate 40, and protruded electrodes 42 are provided on the circuit substrate 40, in a similar manner as the semiconductor element 21 and the circuit substrate 20 are electrically connected.

Next, as shown in FIG. 8(a), the circuit substrate 20 having the semiconductor element 21 mounted thereon is disposed over the base substrate 10. The wiring pattern 16 of the base substrate 10 and the protruded electrodes 22 are bonded together to electrically connect the wiring pattern 16 and the protruded electrodes 22. The wiring pattern 16 and the protruded electrodes 22 may be bonded together by metal bonding, such as, solder bonding, eutectic bonding, bonding using inter-metal diffusion or the like, or bonded together by adhesive bonding using an anisotropic conductive adhesive, a dielectric adhesive, a conductive adhesive, or the like.

Next, as indicated in FIG. 8(b), the circuit substrate 30 is positioned with respect to the base substrate 10 in a manner that at least the circuit substrate 20 is placed in a position that avoids the region where the protruded electrodes 32 of the circuit substrate 30 are formed. In this instance, the circuit substrate 30 may be moved in directions indicated by the arrows, or the base substrate 10 may be moved in directions indicated by the arrows for position alignment. For example, if the protruded electrodes 32 are formed along the outer circumference of the circuit substrate 30, the position alignment is conducted such that the circuit substrate 20 is positioned below a region that is surrounded by the region where the protruded electrodes 32 are formed.

As indicated in FIG. 8(c), the circuit substrate 30 having the semiconductor element 31 mounted thereon is disposed over the circuit substrate 20. The wiring pattern 16 of the base substrate 10 is bonded with the protruded electrodes 32 to electrically connect the wiring pattern 16 to the protruded electrodes 32. The wiring pattern 16 and the protruded electrodes 32 may be bonded together by metal bonding, such as, solder bonding, eutectic bonding, bonding using inter-metal diffusion or the like, or bonded together by adhesive bonding using an anisotropic conductive adhesive, a dielectric adhesive, a conductive adhesive, or the like.

Further, if another circuit substrate, for example, a circuit substrate 40, is provided over the circuit substrate 30, the circuit substrate 40 having the semiconductor element 41 mounted thereon is mounted over the circuit substrate 30, and the wiring pattern 16 of the base substrate 10 is electrically connected to the protruded electrodes 42. In this instance, as indicated in FIG. 1, the wiring pattern 16 of the base substrate 10 and the protruded electrodes 42 are bonded together to electrically connect the wiring pattern 16 of the base substrate 10 and the protruded electrodes 42. Also, as indicated in FIG. 7, a wiring pattern of a circuit substrate that is located below the circuit substrate 40 may be bonded to the protruded electrodes 42 to electrically connect the wiring pattern 16 of the base substrate 10 and the protruded electrodes 42. For example, the wiring pattern 36 of the circuit substrate 30 may be bonded to the protruded electrodes 42.

Also, if there is another circuit substrate, such as a circuit substrate 40, between the circuit substrate 20 and the circuit substrate 30, the circuit substrate 40 having the semiconductor element 41 mounted thereon is mounted over the circuit substrate 20 to electrically connect the wiring pattern 16 of the base substrate 10 and the protruded electrodes 42, after the step of bonding the protruded electrodes 22 of the circuit substrate 20 and the wiring pattern 16, and before the step of bonding the protruded electrodes 32 of the circuit substrate 30 and the wiring pattern 16. In this instance, for example, as indicated in FIG. 4, the wiring pattern 16 of the base substrate 10 and the protruded electrodes 42 may be bonded, to electrically connect the wiring pattern 16 of the base substrate 10 and the protruded electrodes 42. Also, a wiring pattern of a circuit substrate located below the circuit substrate 40 may be bonded to the protruded electrodes 42, to electrically connect the wiring pattern 16 of the base substrate 10 and the protruded electrodes 42. For example, as indicated in FIG. 6, the wiring pattern 26 of the circuit substrate 20 may be bonded to the protruded electrodes 42.

The protruded electrodes 42 and any of the wiring patterns may be bonded together by metal bonding, such as, solder bonding, eutectic bonding, bonding using inter-metal diffusion or the like, or bonded together by adhesive bonding using an anisotropic conductive adhesive, a dielectric adhesive, a conductive adhesive, or the like.

When bonding the protruded electrodes 22, 32 or 42 with any of the wiring patterns of the base substrate or the circuit substrates, if a step of applying energy, such as, heating or irradiating light, to the bonding section is required, such a step of applying energy to each bonding section may be conducted after each step of mounting each of the circuit substrates over the base substrate 10, or energy may be applied to bonding sections all together after a plurality of circuit substrates are mounted over the base substrate 10.

In the description of the embodiments of the present invention above, the protruded electrodes 22, 32 and 42 are provided on the circuit substrates 20, 30 and 40, respectively, which are disposed over the base substrate 10, and they are mounted on the base substrate 10. However, without being limited to this embodiment, protruded electrodes 22, 32 and 42 may be bonded to a base wiring 16 of the base substrate 10 in advance. Circuit substrates 20, 30 and 40 may be positioned with respect to the protruded electrodes 22, 32 and 42, respectively. Circuit substrates 20, 30 and 40 may be mounted on the protruded electrodes 22, 32 and 42, respectively, and the protruded electrodes 22, 32 and 42 may be electrically connected to wiring patterns, respectively.

Also, by mounting a semiconductor device in accordance with the embodiment of the present invention on an electronic device such as a portable telephone, a digital camera or the like, the electronic device can be made smaller in size and thinner.

As described above, in accordance with the present invention, a semiconductor device, a method for manufacturing the same or an electronic device includes a base substrate including a base wiring pattern. A first circuit substrate is disposed over the base substrate and includes a first wiring pattern A first semiconductor element is mounted on the first circuit substrate and includes a first electrode that is electrically connected to the first wiring pattern A second circuit substrate is disposed over the first circuit substrate and includes a second wiring pattern and a second semiconductor element is mounted on the second circuit substrate and includes a second electrode that is electrically connected to the second wiring pattern. A first protruded electrode is electrically connected to the first wiring pattern and provided protruding from the first circuit substrate and bonded to the base wiring pattern and a second protruded electrode is electrically connected to the second wiring pattern and provided protruding from the second circuit substrate and bonded to the base wiring pattern. As a result, routing of wirings within each circuit wiring substrate can be made easier, the number of components such as circuit substrates can be reduced, and a thinner body of stacked layers can be attained.

What is claimed is:

1. A semiconductor device, comprising:
a base substrate including a base wiring pattern;
a first circuit substrate disposed over the base substrate and including a first wiring pattern;
a first semiconductor element mounted on the first circuit substrate and including a first electrode electrically connected to the first wiring pattern;
a second circuit substrate disposed over the first circuit substrate and including a second wiring pattern;
a second semiconductor element mounted on the second circuit substrate and including a second electrode electrically connected to the second wiring pattern;
a first protruded electrode electrically connected to the first wiring pattern and provided protruding from the first circuit substrate and bonded to the base wiring pattern; and
a second protruded electrode electrically connected to the second wiring pattern and provided protruding from the second circuit substrate and bonded to the base wiring pattern.

2. The semiconductor device according to claim 1, further comprising a third semiconductor element mounted on the base substrate and including a third electrode electrically connected to the base wiring pattern.

3. The semiconductor device according to claim 1, wherein the second protruded electrode is thicker than the first protruded electrode.

4. The semiconductor device according to claim 1, further comprising another semiconductor element layered on the first semiconductor element.

5. The semiconductor device according to claim 1, further comprising another semiconductor element layered on the second semiconductor element.

6. A method for manufacturing a semiconductor device, comprising:
disposing a first circuit substrate, which is a circuit substrate having a first wiring pattern, having a first semiconductor element mounted thereon including a first electrode that is electrically connected to the first wiring pattern over a base wiring substrate including a base wiring pattern;
bonding a first protruded electrode provided between the first circuit substrate and the base substrate to the base wiring pattern to electrically connect the first wiring pattern and the base wiring pattern;
disposing a second circuit substrate, which is a circuit substrate including a second wiring pattern, having a second semiconductor element mounted thereon including a second electrode that is electrically connected to the second wiring pattern over the first circuit substrate; and
bonding a second protruded electrode provided between the second circuit substrate and the base substrate to the base wiring pattern to electrically connect the second wiring pattern and the base wiring pattern.

7. The method for manufacturing a semiconductor device according to claim 6, further comprising:
protruding the second protruded electrode from a surface of the second circuit substrate, and
positioning the second circuit substrate and the base substrate are such that the first circuit substrate is positioned below a region that avoids a region where the second protruded electrode of the second circuit substrate is formed after the step of electrically connecting the first wiring pattern and the base wiring pattern, and before the step of disposing the second circuit substrate over the first circuit substrate.

8. An electronic device comprising a semiconductor device recited in any one of claim 1.

9. The semiconductor device according to claim 1, wherein the base substrate is equipped with a dielectric substrate material.

10. The semiconductor device according to claim 1, wherein the base wiring pattern has a multiple layered wiring structure.

11. The semiconductor device according to claim 1, wherein the second semiconductor element includes electrodes.

12. The semiconductor device according to claim 1, wherein the base wiring pattern includes lands bonded to the first and second protruded electrodes.

13. The semiconductor device according to claim 1, wherein the first and second protruded electrodes are bonded to the base wiring pattern selected from the group consisting of anisotropic conductive adhesive, dielectric adhesive, alloy bonding, metal bonding and inter-metal diffusion bonding.

14. The semiconductor device according to claim 11, wherein the electrodes are formed from electrode pads.

15. The semiconductor device according to claim 11, wherein the electrodes of the second semiconductor element are electrically connected to the second wiring pattern by a face-down bonding method.

16. The semiconductor device according to claim 11, wherein the electrodes of the second semiconductor element are electrically connected to the second wiring pattern by a wire-binding method.

17. The semiconductor device according to claim 1, wherein the protruded electrodes are formed from a conductive member.

18. The semiconductor device according to claim 17, wherein the conductive member includes a structure in which a plurality of conductive films are stacked in layers.

19. The semiconductor device according to claim 17, wherein the conductive member is selected from the group consisting of a metal, a metal compound, an alloy, a conductive paste and a solder metal.

20. A semiconductor device, comprising:
a base substrate including a base wiring pattern;
a first circuit substrate disposed over the base substrate and including a first wiring pattern;
a first semiconductor element mounted on the first circuit substrate and including a first electrode electrically connected to the first wiring pattern;
a second circuit substrate disposed over the first circuit substrate and including a second wiring pattern;
a second semiconductor element mounted on the second circuit substrate and including a second electrode electrically connected to the second wiring pattern; and
means for electrically connecting to the first and second wiring patterns, protruding from the first and second circuit substrates and bonding to the base wiring pattern.
